(19) United States
(12) Patent Application Publication
(10) Pub. No.: US 2015/0177585 A1
(43) Pub. Date: Jun. 25, 2015

(54) Systems, Methods, and Apparatus for Integrated Glass Units Having Adjustable Transmissivities

(71) Applicant: Intermolecular, Inc., San Jose, CA (US)

(72) Inventors: Guowen Ding, San Jose, CA (US); Minh Huu Le, San Jose, CA (US)

(73) Assignee: Intermolecular, Inc., San Jose, CA (US)

(21) Appl. No.: 14/135,462

(22) Filed: Dec. 19, 2013

(51) Int. Cl. G02F 1/15; C23C 16/40

(52) U.S. Cl. CPC G02F 1/1523; G02F 1/1525; C23C 16/405; C23C 16/407; C23C 16/409

(57) ABSTRACT

Disclosed herein are systems, methods, and apparatus for forming adjustable windows may include a substrate and a first conducting oxide layer formed over the substrate. The adjustable windows may further include a spectral tuning layer formed over the first conducting oxide layer and an ion conductor layer formed over the spectral tuning layer. The adjustable windows may also include an ion storage layer formed over the ion conductor layer and a second conducting oxide layer formed over the ion storage layer. In some embodiments, the spectral tuning layer may be configured to change an infrared transmissivity of the adjustable window. Furthermore, the spectral tuning layer may be configured to toggle a solar heat gain ratio coefficient of the adjustable window between two or more solar heat gain ratio coefficients.

### TECHNICAL FIELD

The present disclosure relates generally to films configured to provide an adjustable transmissivity, and more particularly to such films deposited on transparent substrates.

### BACKGROUND

Electrochromic windows may include materials that exhibit a reversible electrochemically-mediated change in an optical property when placed in a different electronic state, typically by being subjected to a voltage change. The optical property is typically one or more of color, transmittance, absorbance, and reflectance of visible light. Electrochromic materials may be incorporated into, for example, windows and mirrors. The color, transmittance, absorbance, and/or reflectance of such windows and mirrors may be changed by inducing a change in the electrochromic material. Conventional electrochromic windows typically cause noticeable changes in a color of visible light, which may be undesirable in many applications. Moreover, conventional electrochromic windows may suffer from a lack of uniformity in a color change when implemented as large window panels due to a lack of uniformity in a voltage applied to the electrochromic windows. Accordingly, conventional electrochromic windows remain limited.

### SUMMARY

Disclosed herein are systems, methods, and apparatus for forming adjustable windows. In some embodiments, the adjustable windows may include a substrate and a first conducting oxide layer formed over the substrate. The adjustable windows may further include a spectral tuning layer formed over the first conducting oxide layer and an ion conductor layer formed over the spectral tuning layer. The adjustable windows may also include an ion storage layer formed over the ion conductor layer and a second conducting oxide layer formed over the ion storage layer. In some embodiments, the spectral tuning layer may be configured to change an infrared transmissivity of the adjustable window. The spectral tuning layer may be substantially crystalline. Furthermore, the spectral tuning layer may comprise tungsten oxide.

In some embodiments, the spectral tuning layer may be configured to substantially change a transmissivity of the adjustable windows in a wavelength range of about 790 nm to 2500 nm. For example, the spectral tuning layer may be configured to change a transmissivity of the adjustable window in a wavelength range of about 790 nm to 2500 nm by between about 40% and 70%. Furthermore, the spectral tuning layer may be further configured to not substantially change a transmissivity of the adjustable window in a wavelength range of about 380 nm to 780 nm. For example, the spectral tuning layer may be further configured to change a transmissivity of the adjustable window in a wavelength range of about 380 nm to 780 nm by less than 20%. In some embodiments, the ion conductor layer may include lithium niobium oxide and the ion storage layer may include niobium oxide. Furthermore, the first conducting oxide layer and the second conducting oxide layer may include indium tin oxide.

In some embodiments, the spectral tuning layer may be configured to toggle a solar heat gain ratio coefficient of the adjustable window between two or more solar heat gain ratio coefficients. Furthermore, the spectral tuning layer may be configured to toggle the solar heat gain ratio coefficient of the adjustable window between a first solar heat gain ratio coefficient having a value of 1.52 and a second solar heat gain ratio coefficient having a value of 1.19. In some embodiments, the adjustable window is configured to have a color of a substrate-side reflection that changes by less than 3% in response to toggling between the first solar heat gain ratio coefficient and the second solar heat gain ratio coefficient.

Also disclosed herein are methods of changing an infrared transmissivity of adjustable windows. The methods may include applying a first voltage at an adjustable window. The adjustable window may include a first conducting oxide layer, a second conducting oxide layer, and a spectral tuning layer formed between the first conducting oxide layer and the second conducting oxide layer. The methods may further include generating an electrical potential between the first conducting oxide layer and the second conducting oxide layer. The methods may also include changing an infrared transmissivity of the spectral tuning layer in response to generating the electrical potential. In some embodiments, the first voltage causes the infrared transmissivity of the adjustable window to increase.

In some embodiments, the methods may further include applying a second voltage at the adjustable window and changing the infrared transmissivity of the adjustable window in response to applying the second voltage. The second voltage may cause the infrared transmissivity of the adjustable window to decrease. In some embodiments, the first conducting oxide layer and the second conducting oxide layer include indium tin oxide.

Further disclosed herein are methods of forming an adjustable window. The methods may include forming or providing a substrate and forming a first conducting oxide layer over the substrate. The methods may further include forming a spectral tuning layer over the first conducting oxide layer and forming an ion conductor layer over the spectral tuning layer. The methods may also include forming an ion storage layer over the ion conductor layer and forming a second conducting oxide layer over the ion storage layer. In some embodiments, the spectral tuning layer is operable to change an infrared transmissivity of the adjustable window.

These and other embodiments are described further below with reference to the figures.

### BRIEF DESCRIPTION OF THE DRAWINGS

To facilitate understanding, the same reference numerals have been used, where possible, to designate common components presented in the figures. The drawings are not to scale and the relative dimensions of various elements in the drawings are depicted schematically and not necessarily to scale. Various embodiments can readily be understood by considering the following detailed description in conjunction with the accompanying drawings, in which:

FIG. 1 is a schematic illustration of a cross-section of a portion of an adjustable window that may include a spectral tuning layer configured to change an infrared transmissivity of the adjustable window, implemented in accordance with some embodiments.

FIG. 2 is a schematic illustration of a cross-section of a portion of an integrated glass unit that may include a spectral tuning layer and a low emissivity stack of layers, implemented in accordance with some embodiments.

FIG. 3 illustrates an example of a method for using an adjustable window which includes a spectral tuning layer, implemented in accordance with some embodiments.

FIG. 4 is a process flowchart corresponding to a method 400 of forming an adjustable window that may include a spectral tuning layer, implemented in accordance with some embodiments.

FIG. 5 is a graph illustrating transmission properties of an adjustable window that may include a spectral tuning layer, implemented in accordance with some embodiments.

### DETAILED DESCRIPTION OF EXAMPLE EMBODIMENTS

In the following description, numerous specific details are set forth in order to provide a thorough understanding of the presented concepts. The presented concepts may be practiced without some or all of these specific details. In other instances, well known process operations have not been described in detail so as to not unnecessarily obscure the described concepts. While some concepts will be described in conjunction with the specific embodiments, it will be understood that these embodiments are not intended to be limiting.

### Introduction

Conventional electrochromic windows include an electrochromic layer that may change between a colored, translucent state and a transparent state in response to the application of a voltage. Conventional electrochromic windows typically adjust some, if not all visible light, thus resulting in visible changes in opacity and noticeable changes in color. Such effects might not be desirable during the winter, when additional sunlight is desired. Thus, conventional electrochromic windows are not suitable for both summer and winter use. Moreover, because voltages applied to conventional electrochromic windows are not always uniform, conventional electrochromic windows often experience a change in color that is not uniform across the entire window and is visually undesirable.

Disclosed herein are adjustable windows that include spectral tuning layers operable to adjust or change a transmissivity of the windows in an infrared spectral range while not adjusting a transmissivity of visible light. Accordingly, the solar heat gain coefficient of the adjustable windows may be adjusted without affecting transmissivity of the windows in the visible range of light. For example, a spectral tuning layer may include crystalline tungsten oxide. The use of tungsten oxide that is crystalline instead of amorphous may shift the absorption characteristics of the tungsten oxide such that infrared wavelengths are affected while visible light is not affected. In this example, the adjustable window may be adjusted from a solar heat gain coefficient of 1.19 to 1.52, and similarly from 1.52 to 1.19. In this way, spectral tuning layers may toggle the adjustable windows back and forth between a solar heat gain coefficient appropriate for summer use and a solar heat gain coefficient appropriate for winter use without substantially affecting a transmissivity of the adjustable windows to visible light. Because the transmissivity of the adjustable windows to visible light is not affected, there are no visible changes in a color of the adjustable windows, and there are no visible changes in uniformity of a transmissivity of the adjustable windows due to lack of uniformity of a voltage applied to the adjustable windows.

Examples of Integrated Glass Units which Include Spectral Tuning Layers

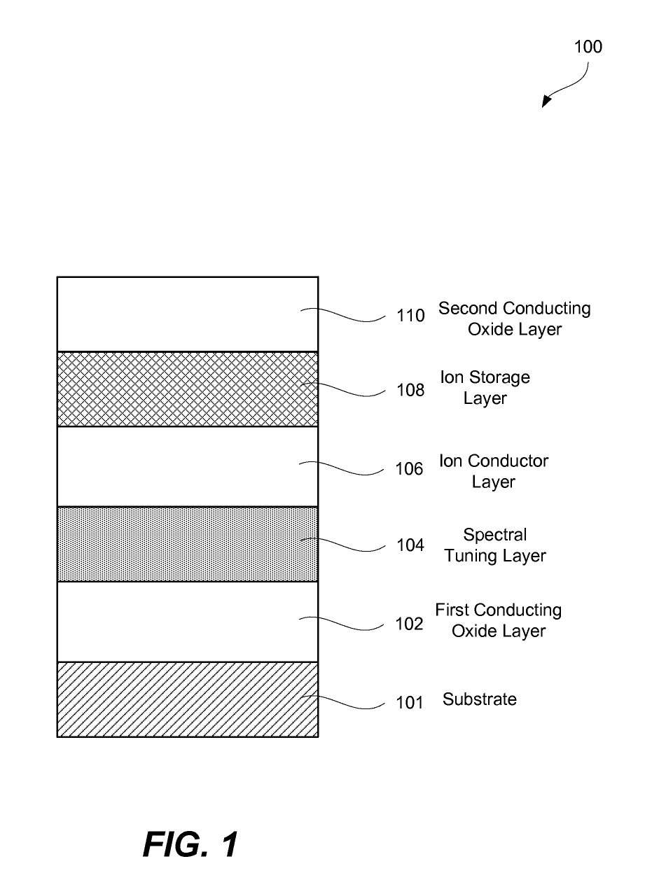

FIG. 1 is a schematic illustration of a cross-section of a portion of an adjustable window that may include a spectral tuning layer configured to change an infrared transmissivity of the adjustable window, implemented in accordance with some embodiments. In some embodiments, an adjustable window may be a window that includes one or more layers configured to change transmissivity in response to the application of one or more voltages to the adjustable window. As discussed in greater detail below, a voltage may be applied across two conducting layers, such as first conducting oxide layer 102 and second conducting oxide layer 110. The voltage may induce the migration of ions, such as lithium ions, among one or more layers within the adjustable window. A layer, such as spectral tuning layer 104, may be configured to change one or more optical characteristics in response the presence or removal of ions, which may be lithium ions. For example, the migration of a high concentration of lithium ions into spectral tuning layer 104 may selectively alter its infrared transmissivity and make it less transmissive to infrared radiation. In this way, a solar heat gain ratio of the adjustable window may be adjusted without changing the adjustable window's transmissivity of visible light.

Accordingly, article 100 may include substrate 101, which may be made of any suitable material. Substrate 101 may be opaque, translucent, or transparent to the visible light. Specifically, a transparent glass substrate may be used for this and other applications. For purposes of this disclosure, the term “transparency” is defined as a substrate characteristic related to a visible light transmittance through the substrate. The term “translucent” is defined as a property of passing the visible light through the substrate and diffusing this energy within the substrate, such that an object positioned on one side of the substrate is not visible on the other side of the substrate. The term “opaque” is defined as a visible light transmittance of 0%. Some examples of suitable materials for substrate 101 include, but are not limited to, plastic substrates, such as acrylic polymers (e.g., polyacrylates, polyalkyl methacrylates, including polymethyl methacrylates, polyethyl methacrylates, polypropyl methacrylates, and the like), polyurethanes, polycarbonates, polyalkyl terephthalates (e.g., polyethylene terephthalate (PET), polypropylene terephthalates, polybutylene terephthalates, and the like), polysiloxane containing polymers, copolymers of any monomers for preparing these, or any mixtures thereof. Substrate 101 may be also made from one or more metals, such as galvanized steel, stainless steel, and aluminum. Other examples of substrate materials include ceramics, glass, and various mixtures or combinations of any of the above.

Article 100 may further include first conducting oxide layer 102 which may be made of any suitable material. For example, first conducting oxide layer 102 may be made from one or more conductive oxides, thin metallic coatings, conductive metal nitrides, and composite conductors. In some embodiments, first conducting oxide layer 102 may be transparent. Accordingly, first conducting oxide layer 102 may be made of a transparent conducting oxide (TCO) which may be a metal oxide which may or may not be doped with one or more metals. Examples of such metal oxides and doped metal oxides include indium oxide, indium tin oxide, doped indium oxide, tin oxide, doped tin oxide, zinc oxide, aluminum zinc oxide, doped zinc oxide, ruthenium oxide, and doped ruthenium oxide. In some embodiments, thin metallic coatings that are substantially transparent may also be used. Examples of metals used for such thin metallic coatings include transition metals including gold, platinum, silver, aluminum, and nickel alloy. In some embodiments, conductive nitrides may also be included in first conducting oxide layer 102. Examples of conductive nitrides include titanium nitrides, tantalum nitrides, titanium oxynitrides, and tantalum oxynitrides. In some embodiments, first conducting oxide layer 102 may be coupled to an external voltage source via a coupler, such as a wire leg or a bus bar, which may be coupled to the edge of article 100 which may be included in an adjustable window.

In some embodiments, second conducting oxide layer 110 may be made of any of the suitable materials described above with reference to first conducting oxide layer 102. First conducting oxide layer 102 and second conducting oxide layer 110 may be made of the same or different materials. Moreover, second conducting oxide layer 110 may also be coupled to the same external voltage source as first conducting oxide layer 102. When activated, the external voltage source may establish an electric potential between first conducting oxide layer 102 and second conducting oxide layer 110. In this way, an electric potential or voltage may be applied to one or more layers included in article 100. In some embodiments, first conducting oxide layer 102 and second conducting oxide layer 110 may each have a thickness of between about 50 nm and 500 nm. Moreover, first conducting oxide layer 102 and second conducting oxide layer 110 may each have a sheet resistance of about 10 Ohms per square.

In some embodiments, article 100 further includes spectral tuning layer 104 which may be a layer configured to adjust or change a transmissivity of at least a portion of the electromagnetic spectrum transmitted through article 100 and an adjustable window that may include article 100. According to some embodiments, spectral tuning layer 104 may contain one or more of a number of different materials, including metal oxides. Such metal oxides may include molybdenum oxide, niobium oxide, titanium oxide, copper oxide, iridium oxide, chromium oxide, manganese oxide, vanadium oxide, nickel oxide, and cobalt oxide. Most preferably, spectral tuning layer 104 may include tungsten oxide. In some embodiments, the tungsten oxide included in spectral tuning layer is substantially crystalline. For example, spectral tuning layer 104 may include crystalline tungsten oxide that is between about 90 volume % to 100 volume % crystalline as determined by X-ray diffraction.

In some embodiments, the use of crystalline tungsten oxide shifts the absorption characteristics of spectral tuning layer 104 such that spectral tuning layer 104 substantially changes a transmissivity of the article 100 and an adjustable window that includes article 100 in a wavelength range of about 790 nm to 2500 nm. However, unlike conventional layers which may include amorphous layers, spectral tuning layer 104 does not substantially change a transmissivity of article 100 or the adjustable window in a wavelength range of about 380 nm to 780 nm. For example, spectral tuning layer 104 may be configured to change a transmissivity of the adjustable window in a wavelength range of about 790 nm to 2500 nm by between about 60% and 70%, and may be further configured to change a transmissivity of the adjustable window in a wavelength range of about 380 nm to 780 nm by less than 10%.

Accordingly, in response to the application of one or more voltages to first conducting oxide layer 102 and second conducting oxide layer 110, a transmissivity of spectral tuning layer 104 may be changed for infrared wavelengths, but not for visible wavelengths. For example, when transitioned to a first state, spectral tuning layer 104 may include little to no lithium ions, and may be in a transmissive state which is highly transmissive to both visible spectra and infrared spectra. When transitioned to a second state, spectral tuning layer 104 may include a high concentration of lithium ions (passed via ion conductor layer 106 discussed in greater detail below) and may be minimally transmissive to infrared spectra while still being highly transmissive to visible spectra. As stated above, a transmissivity of the adjustable window to visible light remains substantially unaffected. Because of this, any changes in a uniformity of the voltage applied to the adjustable window are not visible, and the window appears to be uniformly transmissive.

Moreover, the selective adjustment of infrared transmissivity of article 100 provided by spectral tuning layer 104 enables the adjustment of the solar heat gain of article 100 and an adjustable window that includes article 100. When spectral tuning layer 104 is in the first state, article 100 and the adjustable window may have a solar heat gain ratio coefficient (SHGC) that is relatively high, and is about 1.52. Such a high SHGC may be suitable for winter applications where increased heat retention is desired. When spectral tuning layer 104 is in the second state, article 100 and the adjustable window may have a SHGC that is relatively low, and is about 1.19. Such a low SHGC may be suitable for summer applications where increased heat retention is not desired. In this way, a single adjustable window that includes article 100 and spectral tuning layer 104 may be adjusted for use with both summer and winter applications.

In some embodiments, article 100 may include ion conductor layer 106 which may be made of a material that functions as an electrolyte and provides a medium through which ions are transported in response to the application of one or more voltages to article 100. In some embodiments, ion conductor layer 106 may be highly conductive to the relevant ions for spectral tuning layer 104 and ion storage layer 108, discussed in greater detail below. Moreover, ion conductor layer 106 may have a sufficiently low electron conductivity such that negligible electron transfer takes place during normal operation. In some embodiments, ion conductor layer 106 may be relatively thin to achieve a high ionic conductivity that permits fast ion conduction and hence fast switching of optical states. In some embodiments, ion conductor layer 106 may be made of one or more materials such silicates, silicon oxides, tungsten oxides, tantalum oxides, niobium oxides, and borates which may be doped with different dopants, such as lithium. Accordingly, ion conductor layer 106 may include lithium niobium oxide. In some embodiments, ion conductor layer 106 may be between about 5 nm to 100 nm thick.

Article 100 may also include ion storage layer 108 which may be a layer configured to provide a reservoir for ions within article 100. More specifically, ion storage layer 108 may store ions when spectral tuning layer 104 is in a neutral state that is highly transmissive in the infrared band. In some embodiments, ion storage layer may be made of a metal oxide such as niobium oxide, nickel oxide, nickel tungsten oxide, nickel vanadium oxide, nickel chromium oxide, nickel aluminum oxide, nickel manganese oxide, nickel magnesium oxide, chromium oxide, manganese oxide, cerium titanium oxide, cerium zirconium oxide, nickel oxide, nickel-tungsten oxide, and vanadium oxide. In some embodiments, ion storage layer 108 is made of a material that retains a high transmittance and color neutrality even if it retains high quantities of the ions relevant to spectral tuning layer 104, such as lithium. For example, if spectral tuning layer 104 includes crystalline tungsten oxide, and ion conductor layer 106 includes lithium niobium oxide, ion storage layer may include niobium oxide. In this example, when spectral tuning layer 104 is in or is transitioned to a neutral or bleached state, lithium ions may pass through ion conductor layer 106 and be stored in ion storage layer 108. Despite storing the lithium ions, ion storage layer 108 may retain high transmissivity and color neutrality.

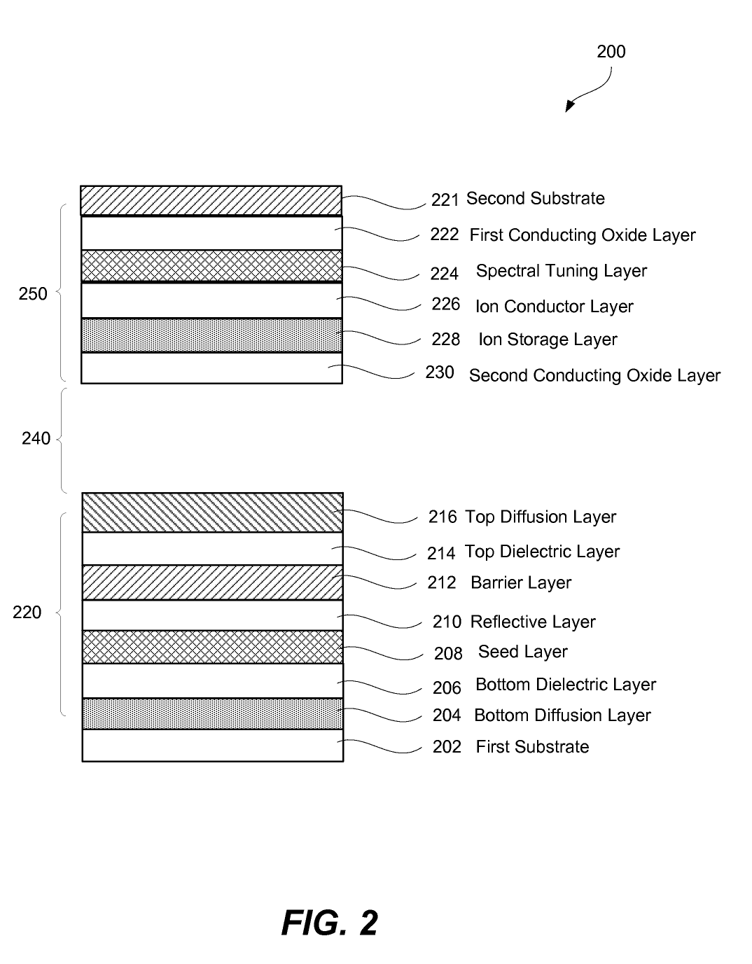

FIG. 2 is a schematic illustration of a cross-section of a portion of an integrated glass unit that may include a spectral tuning layer and a low emissivity stack of layers, implemented in accordance with some embodiments. Thus, FIG. 2 illustrates how one or more layers similar to those described with reference to FIG. 1 may be integrated with other layers and other functionalities, such as low emissivity production coatings, in an integrated glass unit (IGU).

Accordingly, stack 220 may include one or more layers configured to provide low emissivity functionality for IGU 200. Low emissivity may refer to a quality of a surface that emits low levels of radiant thermal energy. Emissivity is the value given to materials based on the ratio of heat emitted compared to a blackbody, on a scale of 0 (for a perfect reflector) to 1 (for a back body). For example, the emissivity of a polished silver surface may be 0.01. Reflectivity is inversely related to emissivity. When values of reflectivity and emissivity are added together, their total is equal 1. Low emissivity coatings may be used to modify or alter the emissivity of IGU 200 with respect to thermal energy. Accordingly, stack 220 may include several layers, such as reflective layer 210 which may be formed over first substrate 202 and protected by a barrier layer 212. Other layers in stack 220 may include bottom diffusion layer 204, top diffusion layer 216, bottom dielectric layer 206, top dielectric layer 214, and seed layer 208. As discussed above with reference to substrate 101 of FIG. 1, first substrate 202 and second substrate 221 may be made of any suitable material. As shown in FIG. 2, first substrate 202 and second substrate 221 may be panes of glass that form the outer layers of IGU 200, which may be enclosed and sealed around the edges of first substrate 202 and second substrate 221.

Bottom diffusion layer 204 and top diffusion layer 216 may be two layers of stack 220 that protect the entire stack 220 from the environment and improve chemical and/or mechanical durability of stack 220. Diffusion layers 204 and 216 may be made from the same or different materials and may have the same or different thickness. In some embodiments, one or both diffusion layers 204 and 216 are formed from silicon nitride. In some embodiments, silicon nitride may be doped with aluminum and/or zirconium. The dopant concentration may be between about 0% to 20% by weight. In some embodiments, silicon nitride may be partially oxidized. Silicon nitride diffusion layers may be silicon-rich, such that their compositions may be represented by the following expression, Si_{X}N_{Y}, where the X-to-Y ratio is between about 0.8 and 1.0. The refraction index of one or both diffusion layers 204 and 216 may be between about 2.0 and 2.5 or, more specifically, between about 2.15 to 2.25. The thickness of one or both diffusion layers 204 and 216 may be between about 5 nm and 30 nm or, more specifically, between about 10 nm and 20 nm.

Stack 220 may also include dielectric layers 206 and 214 that may be used to control reflection characteristics of reflective layer 210 as well as overall transparency and color of stack 220 and, in some embodiments, of IGU 200. Dielectric layers 206 and 214 may be made from the same or different materials and may have the same or different thickness. For example, a dielectric layer, such as dielectric layer 206 and/or dielectric layer 214, may be made of TiO₂, ZnO, SnO₂, SiAlN, or ZnSn. In some embodiments, one or both dielectric layers 206 and 214 may include dopants, such as Al, Ga, In, Mg, Ca, Sr, Sb, Bi, Ti, V, Y, Zr, Nb, Hf, or Ta. Dielectric layers 206 and 214 can each include different dielectric materials with similar refractive indices or different materials with different refractive indices. The relative thicknesses of the dielectric films can be varied to optimize thermal-management performance, aesthetics, and/or durability of IGU 200.

In some embodiments, stack 220 includes seed layer 208. Seed layer 208 may be formed from ZnO, SnO₂, Sc₂O₃, Y₂O₃, TiO₂, ZrO₂, HfO₂, V₂O₅, Nb₂O₅, Ta₂O₅, CrO₃, WO₃, MoO₃, various combinations thereof, or other metal oxides. The material of seed layer 208 may be in a crystalline phase (e.g. greater than 30% crystalline as determined by X-ray diffraction). Seed layer 208 may function as a nucleation template for overlying layers, e.g., reflective layer 210. In some embodiments, the thickness of seed layer 208 is between about 3 nm and 30 nm, such as about 20 nm.

Stack 220 may also include reflective layer 210, which may be formed from silver. The thickness of this layer may be between about 5 nm and 20 nm or, more specifically, between about 10 nm and 15 nm. Reflective layer 210 may have a sheet resistance of between about 6 Ohm/square and 8 Ohm/square when reflective layer 210 has a thickness between 8 nm and 9 nm. The sheet resistance of reflective layer 210 may be between about 2 Ohm/square to 4 Ohm/square for a thickness of reflective layer 210 that is between about 10 nm and 14 nm.

As noted above, stack 220 may include barrier layer 212 to protect reflective layer 210 from oxidation and other damage. In some embodiments, barrier layer 212 may be formed from an alloy of at least nickel, titanium, and niobium. Moreover, barrier layer 212 may be formed from a quaternary alloy that includes nickel, chromium, titanium, and aluminum. The concentration of each metal in this alloy is selected to provide adequate transparency and oxygen diffusion blocking properties. In some embodiments, a combined concentration of nickel and chromium in the barrier layer is between about 20% by weight and 50% by weight or, more specifically, between about 30% by weight and 40% by weight. A weight ratio of nickel to chromium in the alloy may be between about 3 and 5 or, more specifically, about 4. A weight ratio of titanium to aluminum is between about 0.5 and 2, or more, specifically about 1. In some embodiments, the concentration of nickel in the barrier layer is between about 5% and 10% by weight, the concentration of chromium—between about 25% and 30% by weight, the concentration of titanium and aluminum—between about 30% and 35% by weight each. In some embodiments, nickel, chromium, titanium, and aluminum are all uniformly distributed throughout the barrier layer, i.e., its entire thickness and coverage area. Alternatively, the distribution of components may be non-uniform. For example, nickel and chromium may be more concentrated along one interface than along another interface. In some embodiments, a portion of the barrier layer near the interface with the reflective layer includes more nickel for better adhesion to the reflective layer. In some embodiments, substantially no other components other than nickel, chromium, titanium, and aluminum are present in barrier layer 212.

Top diffusion layer 216 may be similar to bottom diffusion layer 204 described above. In some embodiments, top diffusion layer 216 (e.g., formed from silicon nitride) may be more stoichiometric than bottom diffusion layer 204 to give better mechanical durability and give a smoother surface. Bottom diffusion layer 204 (e.g., formed from silicon nitride) can be silicon-rich to make film denser for better diffusion effect.

IGU 200 may also include stack 250 which may include one or more layers configured to adjust an infrared transmissivity of IGU 200. As similarly discussed above with reference to FIG. 1, stack 250 may include first conducting oxide layer 222 which may be formed on second substrate 221, and spectral tuning layer 224 which may be formed on first conducting oxide layer 222. Stack 250 may further include ion conductor layer 226 which may be formed on spectral tuning layer 224, and ion storage layer 228 which may be formed on ion conductor layer 226. Stack 250 may also include second conducting oxide layer 230. First conducting oxide layer 222 and second conducting oxide layer 230 may include a suitable metal oxide, such as indium tin oxide. Moreover, ion conductor layer 226 may be made of lithium niobium oxide, and ion storage layer 228 may be made of niobium oxide.

Spectral tuning layer 224 may be made of crystalline tungsten oxide which may be between about 90 volume % and 100 volume % crystalline as determined by X-ray diffraction.

Spectral tuning layer 224 may be configured to not substantially change a transmissivity of IGU 200 in a wavelength range of about 380 nm to 780 nm, while substantially changing a transmissivity of IGU 200 in a wavelength range of 790 nm to 2500 nm in response to the application of one or more voltages to first conducting oxide layer 222 and second conducting oxide layer 230. Similarly, spectral tuning layer 224 may be configured to adjust a SHGC of IGU 200 between a first SHGC that is relatively high, and is about 1.52, and a second SHGC that is relatively low and is about 1.19.

In some embodiments, stack 250 and stack 220 may be separated by portion 240, which may be a volume of gas that separates the two stacks. In some embodiments, portion 240 may include an inert gas, such as argon. It will be appreciated that any suitable gas or medium may be used.

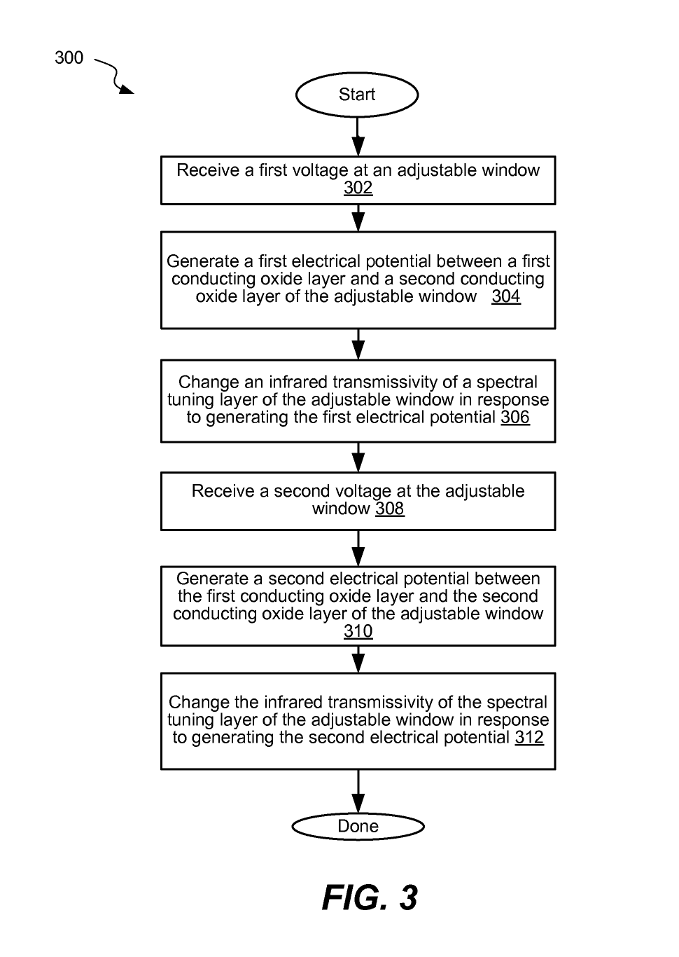

FIG. 3 illustrates an example of a method for using an adjustable window which includes a spectral tuning layer, implemented in accordance with some embodiments. As similarly discussed above, an adjustable window may include a first conducting oxide layer, a spectral tuning layer, an ion conductor layer, an ion storage layer, and a second conducting oxide layer. In some embodiments, method 300 may proceed by applying a first voltage at the adjustable window during operation 302. The adjustable window may be coupled to an external power source. In some embodiments, a user or an automated system may provide an input to the voltage source that causes the voltage source to provide the first voltage to the adjustable window. As discussed previously, the voltage source may be coupled to the first conducting oxide layer and the second conducting oxide layer.

Method 300 may proceed by generating a first electrical potential between the first conducting oxide layer and the second conducting oxide layer of the adjustable window during operation 304. Because the first conducting oxide layer and the second conducting oxide layer are both conductive and effectively spread the voltage provided by the voltage source across their respective surfaces, a first electrical potential is generated between the first conducting oxide layer and the second conducting oxide layer that has an amplitude substantially equal to the voltage provided by the voltage source.

Method 300 may proceed by changing an infrared transmissivity of the spectral tuning layer of the adjustable window in response to generating the first electrical potential during operation 306. In some embodiments, the first electrical potential may cause the migration of lithium ions that may be present in the spectral tuning layer to migrate out of the spectral tuning layer, through the ion conductor layer, and into the ion storage layer. The decrease in lithium ion concentration may cause the infrared transmissivity of the spectral tuning layer to increase.

Method 300 may proceed by applying a second voltage at the adjustable window during operation 308. Thus, to reverse the change in transmissivity, a second voltage may be applied that has an equal amplitude as the first voltage, but has an opposite polarity. The second voltage may be provided by the external power source to the first conducting oxide layer and the second conducting oxide layer of the adjustable window. A second electrical potential may be generated between the first conducting oxide layer and the second conducting oxide layer during operation 310.

Method 300 may proceed by changing the infrared transmissivity of the spectral tuning layer in response to generating the second electrical potential during operation 312. In some embodiments, the second electrical potential may cause the migration of lithium ions from the ion storage layer through the ion conductor layer and into the spectral tuning layer. The increase in lithium ion concentration may cause the infrared transmissivity of the spectral tuning layer to decrease. As discussed above, while the infrared transmissivity may be changed, the transmissivity of the adjustable window to visible light may remain substantially unchanged.

### Processing Examples

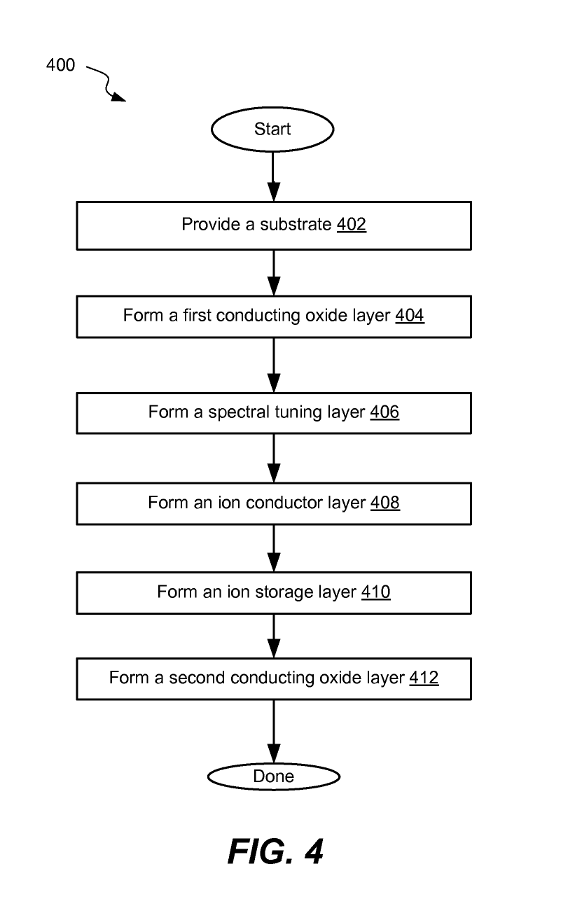

FIG. 4 is a process flowchart corresponding to a method 400 of forming an adjustable window that may include a spectral tuning layer, implemented in accordance with some embodiments. Method 400 may commence with providing a substrate during operation 402. In some embodiments, the provided substrate is a glass substrate. Various examples of suitable substrates are described above with reference to FIG. 1.

Method 400 may proceed with forming a first conducting oxide layer during operation 404. In some embodiments, the first conducting oxide layer may be formed over the substrate. Moreover, the first conducting oxide layer may directly interface the substrate. Any suitable deposition technique may be used to form the first conducting oxide layer. For example, a physical vapor deposition technique, a chemical vapor deposition technique, or an atomic layer deposition technique may be used to form a layer of a material included in the first conducting oxide layer, such as indium tin oxide. In some embodiments, the first conducting oxide layer may be formed such that the first conducting oxide layer partially overlaps an electrical lead, contact, or bus bar which may be coupled to an external voltage source.

Method 400 may proceed with forming a spectral tuning layer during operation 406. In some embodiments, the spectral tuning layer may be formed over the first conducting oxide layer. According to some embodiments, the spectral tuning layer may directly interface the first conducting oxide layer. Any suitable deposition technique may be used to form the spectral tuning layer. For example, a physical vapor deposition technique, a chemical vapor deposition technique, or an atomic layer deposition technique may be used to form a layer of a material included in the spectral tuning layer, such as crystalline tungsten oxide.

Method 400 may proceed with forming an ion conductor layer during operation 408. In some embodiments, the ion conductor layer may be formed over the spectral tuning layer. Furthermore, the ion conductor layer may directly interface the spectral tuning layer. As similarly discussed above, any suitable deposition technique may be used to form the ion conductor layer. For example, a physical vapor deposition technique, a chemical vapor deposition technique, or an atomic layer deposition technique may be used to form a layer of a material included in the ion conductor layer, such as lithium niobium oxide.

Method 400 may proceed with forming an ion storage layer during operation 410. In some embodiments, the ion storage layer may be formed over the ion conductor layer. Moreover, the ion storage layer may directly interface the ion conductor layer. Any suitable deposition technique may be used to form the ion storage layer. For example, a physical vapor deposition technique, a chemical vapor deposition technique, or an atomic layer deposition technique may be used to form a layer of a material included in the ion storage layer, such as niobium oxide.

Method 400 may proceed with forming a second conducting oxide layer during operation 412. In some embodiments, the second conducting oxide layer may be formed over the ion storage layer. Moreover, the second conducting oxide layer may directly interface the ion storage layer. Any suitable deposition technique may be used to form the second conducting oxide layer. For example, a physical vapor deposition technique, a chemical vapor deposition technique, or an atomic layer deposition technique may be used to form a layer of a material included in the second conducting oxide layer, such as indium tin oxide. As similarly discussed above with reference to the first conducting oxide layer, the second conducting oxide layer may also overlap an electrical lead, contact, or bus bar which may be coupled to an external voltage source.

### Simulation Results

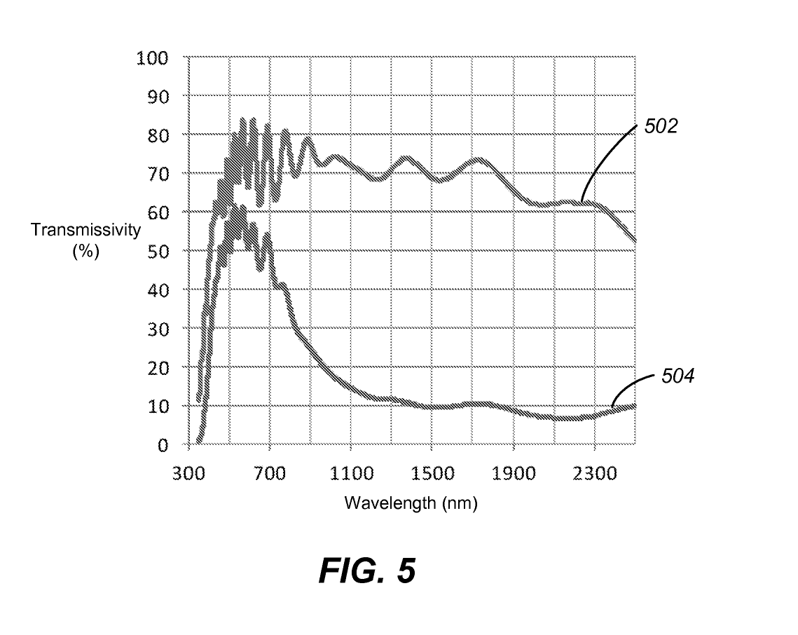

FIG. 5 is a graph illustrating transmission properties of an adjustable window that may include a spectral tuning layer, implemented in accordance with some embodiments. The simulation software used provides highly accurate optical characteristics and is used daily in the production of windows, such as low emissivity windows and adjustable windows. As shown in FIG. 5, transmission characteristics were simulated for an adjustable window including a spectral tuning layer made of crystalline tungsten oxide. The transmission spectra were simulated across visible and infrared wavelengths. Line 502 represents the transmissivity of the adjustable window when in a first state that is highly transmissive in the infrared band and has a high solar heat gain coefficient. Line 504 represents the transmissivity of the adjustable window when in a second state that is not transmissive in the infrared band and has a low solar heat gain coefficient. As similarly discussed above with reference to FIGS. 1-4, an application of one or more voltages to the adjustable window may transition the window between the first state and the second state. As shown in FIG. 5, the transmissivity of the window in the visible spectra (between about 300 nm and 700 nm) is substantially unaffected, while transmissivity in the infrared band (between about 800 nm to 2500 nm) is significantly affected.

TABLE 1
IGU Color performance at high SHGC state

| IGU Color | Y | L* | a* | b* |
|---|---|---|---|---|
| TR | 66.3 | 85.1 | −3.70 | 9.62 |
| IGU_Rin | 17.9 | 49.4 | 0.65 | −3.27 |
| IGU_Rout | 17.0 | 48.2 | −0.43 | 3.97 |

| Thermal Data | Tvis | SHGC | LSG |
|---|---|---|---|
| IGU | 66.3% | 0.558 | 1.19 |

Table 1 illustrates an example of a score card identifying one or more optical properties of an adjustable window that includes a spectral tuning layer when in the first state. Among other properties, Table 1 describes color characteristics of the adjustable window. The color characteristics were simulated and reported using the CIE LAB a*, b* coordinates and scale. In the CIE LAB color system, the “L*” value indicates the lightness of the color, the “a*” value indicates the position between magenta and green (more negative values indicate stronger green and more positive values indicate stronger magenta), and the “b*” value indicates the position between yellow and blue (more negative values indicate stronger blue and more positive values indicate stronger yellow). As shown in Table 1, the values of a* and b* are relatively small indicating a very neutral color of the window.

TABLE 2
IGU Color performance at low SHGC state

| IGU Color | Y | L* | a* | b* |
|---|---|---|---|---|
| TR | 50.2 | 76.2 | −7.80 | 10.18 |
| IGU_Rin | 16.3 | 47.3 | 2.47 | −4.15 |
| IGU_Rout | 13.0 | 42.8 | −5.38 | 4.33 |

| Thermal Date | Tvis | SHGC | LSG |
|---|---|---|---|
| IGU | 50.2% | 0.330 | 1.52 |

Table 2 illustrates an example of a score card identifying one or more optical properties of an adjustable window that includes a spectral tuning layer when in the second state. Table 2 also describes color characteristics of the adjustable window. In this instance, the values of a* and b* are also relatively small indicating a very neutral color of the window. Accordingly, when transitioned between the first state and the second state, the spectral tuning layer and an adjustable window that includes the spectral tuning layer exhibit almost no color shift. Thus, as Table 1 and Table 2 illustrate, the spectral tuning layer may be transitioned from a first state to a second state to change a solar heat gain coefficient of an adjustable window by between about 30% to 50%, while maintaining a color neutrality of the adjustable window.

### CONCLUSION

Although the foregoing concepts have been described in some detail for purposes of clarity of understanding, it will be apparent that certain changes and modifications may be practiced within the scope of the appended claims. It should be noted that there are many alternative ways of implementing the processes, systems, and apparatuses. Accordingly, the present embodiments are to be considered as illustrative and not restrictive.

What is claimed is:

1. A window comprising:
a substrate;
a first conducting oxide layer formed over the substrate;
a spectral tuning layer formed over the first conducting oxide layer;
an ion conductor layer formed over the spectral tuning layer;
an ion storage layer formed over the ion conductor layer; and
a second conducting oxide layer formed over the ion storage layer,
the spectral tuning layer configured to change an infrared transmissivity of the adjustable window in response to an applied voltage.

2. The window of claim 1, wherein the spectral tuning layer is substantially crystalline.

3. The window of claim 2, wherein the spectral tuning layer comprises tungsten oxide.

4. The window of claim 1, wherein the spectral tuning layer is configured to change a transmissivity of the adjustable window in a wavelength range of about 790 nm to 2500 nm by between about 40% and 70%, and is further configured to change a transmissivity of the adjustable window in a wavelength range of about 380 nm to 780 nm by less than 20%.

5. The window of claim 1, wherein the ion conductor layer comprises lithium niobium oxide.

6. The window of claim 1, wherein the ion storage layer comprises niobium oxide.

7. The window of claim 1, wherein the first conducting oxide layer and the second conducting oxide layer comprise indium tin oxide.

8. The window of claim 1, wherein the spectral tuning layer is configured to toggle a solar heat gain ratio coefficient of the adjustable window between two or more solar heat gain ratio coefficients.

9. The window of claim 8, wherein the spectral tuning layer is configured to toggle the solar heat gain ratio coefficient of the adjustable window between a first solar heat gain ratio coefficient having a value of 1.52 and a second solar heat gain ratio coefficient having a value of 1.19.

10. The window of claim 9, wherein the adjustable window is configured to have a color of a substrate-side reflection that changes by less than 3% in response to toggling between the first solar heat gain ratio coefficient and the second solar heat gain ratio coefficient.

11. A method of changing an infrared transmissivity of a window, the method comprising:
applying a first voltage at the adjustable window, the adjustable window including a first conducting oxide layer, a second conducting oxide layer, and a spectral tuning layer formed between the first conducting oxide layer and the second conducting oxide layer; and
generating an electrical potential between the first conducting oxide layer and the second conducting oxide layer,
wherein generating the electrical potential causes an infrared transmissivity of the spectral tuning layer to change.

12. The method of claim 11, wherein the spectral tuning layer comprises tungsten oxide that is between about 90 volume % to 100 volume % crystalline.

13. The method of claim 11, wherein the window further comprises an ion conductor layer made of lithium niobium oxide, and an ion storage layer made of niobium oxide.

14. The method of claim 11, wherein the first voltage causes the infrared transmissivity of the adjustable window to increase.

15. The method of claim 14 further comprising:
applying a second voltage at the window,
the second voltage causing the infrared transmissivity of the window to decrease.

16. The method of claim 11, wherein the first conducting oxide layer and the second conducting oxide layer comprise indium tin oxide.

17. A method of forming a window, the method comprising:
forming a substrate;
forming a first conducting oxide layer over the substrate;
forming a spectral tuning layer over the first conducting oxide layer;
forming an ion conductor layer over the spectral tuning layer;
forming an ion storage layer over the ion conductor layer; and
forming a second conducting oxide layer over the ion storage layer,
the spectral tuning layer operable to change an infrared transmissivity of the window in response to an applied voltage.

18. The method of claim 17, wherein the spectral tuning layer comprises tungsten oxide that is between about 90 volume % to 100 volume % crystalline.

19. The method of claim 17, wherein the ion conductor layer comprises lithium niobium oxide, and wherein the ion storage layer comprises niobium oxide.

20. The method of claim 17, wherein the first conducting oxide layer and the second conducting oxide layer comprise indium tin oxide.
